(19) United States
(12) Patent Application Publication
(10) Pub. No.: US 2023/0230649 A1
(43) Pub. Date: Jul. 20, 2023

(54) METHOD AND DEVICE FOR TESTING MEMORY CHIP

(71) Applicant: CHANGXIN MEMORY TECHNOLOGIES, INC., Hefei City (CN)

(72) Inventor: Dong LIU, Hefei City (CN)

(73) Assignee: CHANGXIN MEMORY TECHNOLOGIES, INC., Hefei City (CN)

(21) Appl. No.: 17/808,701

(22) Filed: Jun. 24, 2022

Related U.S. Application Data
(63) Continuation of application No. PCT/CN2022/081819, filed on Mar. 18, 2022.

(30) Foreign Application Priority Data
Jan. 19, 2022 (CN) 202210059291.6

(51) Int. Cl. G11C 29/12; G11C 29/46; G11C 7/10

(52) U.S. Cl. CPC G11C 29/1201; G11C 7/1048; G11C 29/46; G11C 29/12015

(57) ABSTRACT

A method for testing a memory chip includes the following: test data is written into memory cells of a memory chip to be tested; stored data is read from memory cells; a test result of the memory chip to be tested is generated according to the test data and the stored data. A current voltage of bit line precharge (VBLP) of the memory chip to be tested is smaller than a standard VBLP of the memory chip to be tested, and/or a current sensing delay time (SDT) of the memory chip to be tested is smaller than a standard SDT of the memory chip to be tested.

### CROSS REFERENCE TO RELATED APPLICATIONS

This is a continuation application of International Patent Application No. PCT/CN2022/081819 filed on Mar. 18, 2022, which claims priority to Chinese patent application No. 202210059291.6 filed on Jan. 19, 2022. The disclosures of these applications are hereby incorporated by reference in their entirety.

### BACKGROUND

Dynamic random access memory (DRAM) is a common memory chip and has been widely applied in various electronic devices.

The DRAM is composed of multiple memory cells, each memory cell generally including a capacitor structure and a transistor, a gate of the transistor being connected to a word line (WL), a drain of the transistor being connected to a bit line (BL), and a source of the transistor being connected to the capacitor structure. The voltage signal on the WL can control the transistor to be turned on or turned off, and the data signal stored in the capacitor structure can be read by the BL, or the data signal can be written into the capacitor structure by the BL for storage.

In modem integrated circuit manufacturing processes, the cost of device defects is extremely high, and therefore, there is an urgent need to provide a test method to test whether a failed memory cell exists in a memory chip, so as to improve the yield of the memory chip.

### SUMMARY

Embodiments of the present disclosure relate to the field of semiconductor technology, and in particular, to a method and device for testing a memory chip.

In some embodiments, there is provided a method for testing a memory chip. The method includes the following operations.

Test data is written into memory cells of a memory chip to be tested.

Stored data is read from the memory cells.

A test result of the memory chip to be tested is generated according to the test data and the stored data.

A current voltage of bit line precharge (VBLP) of the memory chip to be tested is smaller than a standard VBLP of the memory chip to be tested, and/or a current sensing delay time (SDT) of the memory chip to be tested is smaller than a standard SDT of the memory chip to be tested.

In some embodiments, there is provided an apparatus for testing a memory chip. The apparatus includes a writing module, a reading module and a processing module.

The writing module is configured to write test data into memory cells of a memory chip to be tested.

The reading module is configured to read stored data from the memory cells.

The processing module is configured to generate a test result of the memory chip to be tested according to the test data and the stored data.

A current VBLP of the memory chip to be tested is smaller than a standard VBLP of the memory chip to be tested, and/or a current SDT of the memory chip to be tested is smaller than a standard SDT of the memory chip to be tested.

In some embodiments, there is provided an electronic device, including a memory and at least one processor.

The memory is configured to store computer-executable instructions.

The at least one processor is configured to execute the computer-executable instructions stored in the memory to cause the at least one processor to implement the method for testing the memory chip as provided in the above-described embodiments.

In some embodiments, there is provided a computer-readable storage medium, the computer-readable storage medium having stored thereon computer-executable instructions that, when being executed by a processor, cause the processor to implement the method for testing the memory chip as provided in the above-described embodiments.

### BRIEF DESCRIPTION OF THE DRAWINGS

FIG. 1 is a layout diagram of a memory chip according to an embodiment of the present disclosure.

FIG. 2 is a schematic structural diagram of a memory cell of a memory chip according to an embodiment of the present disclosure.

FIG. 3 is a schematic flowchart of a method for testing a memory chip according to an embodiment of the present disclosure.

FIG. 4 is a schematic diagram of multiple data topologies of test data provided in an embodiment of the present disclosure.

FIG. 5 is a schematic flowchart of a method for testing a memory chip according to an embodiment of the present disclosure.

FIG. 6 is a first schematic diagram of a data writing flow of a method for testing a memory chip according to an embodiment of the present disclosure.

FIG. 7 is a second schematic diagram of a data writing flow of a method for testing a memory chip according to an embodiment of the present disclosure.

FIG. 8 is a third schematic diagram of a data writing flow of a method for testing a memory chip according to an embodiment of the present disclosure.

FIG. 9 is a fourth schematic diagram of a data writing flow of a method for testing a memory chip according to an embodiment of the present disclosure.

FIG. 10 is a schematic diagram of program modules of an apparatus for testing a memory chip according to an embodiment of the present disclosure.

FIG. 11 is a schematic diagram of a hardware structure of an electronic device according to an embodiment of the present disclosure.

### DETAILED DESCRIPTION

In order to make the objects, technical solutions and advantages of the embodiments of the present disclosure clearer, the technical solutions in the embodiments of the present disclosure will be clearly and completely described below in conjunction with the accompanying drawings of the embodiments of the present disclosure. It is obvious that the described embodiments are some but not all of the embodiments of the present disclosure. All other embodiments obtained by a person of ordinary skill in the art without creative efforts based on the embodiments of the present disclosure are within the scope of the present disclosure. Furthermore, although the disclosure in the application is described in accordance with one or more exemplary examples, it is to be understood that various aspects of these disclosures may also constitute a single complete embodiment.

It should be noted that the brief description of the terms in the present disclosure is merely intended to facilitate understanding of the embodiments described below, and is not intended to limit the embodiments of the present disclosure. Unless otherwise noted, these terms should be understood in their ordinary and usual meanings.

The terms “first” and “second” in the description, claims and the drawings of the application are used to distinguish similar or homogeneous objects or entities, and are not necessarily meant to define a particular order or sequence unless otherwise noted. It should be understood that the terms used in this manner may be interchanged where appropriate, for example, they can be implemented in a sequence other than those given in the diagrams or descriptions of the embodiments of the present disclosure.

Furthermore, the term “comprises” and “have” as well as any variations thereof, are intended to cover but not exclusive inclusion, for example, a product or device containing a series of components is not necessarily limited to those components that are clearly listed, but may include other components that are not clearly listed or inherent to those products or devices.

The term “module” as used herein refers to any known or later developed hardware, software, firmware, artificial intelligence, fuzzy logic, or combination of hardware or/and software code capable of performing functions related to the element.

In modern integrated circuit manufacturing processes, the cost of device defects is extremely high, and therefore, how to test whether a failed memory cell exists in the memory chip is very important.

In view of the above technical problems, an embodiment of the present disclosure provides a method for testing a memory chip. A failed memory cell in the memory chip is more easily exposed by making the memory chip in a poorer operating environment through adjustment, thereby helping to accurately detect whether a failed memory cell exists in the memory chip and improving the yield of the memory chip.

In some embodiments, the memory chip includes multiple bit lines (BLs), multiple word lines (WLs), and multiple memory cells. Each memory cell is connected to a corresponding one WL and a corresponding one BL.

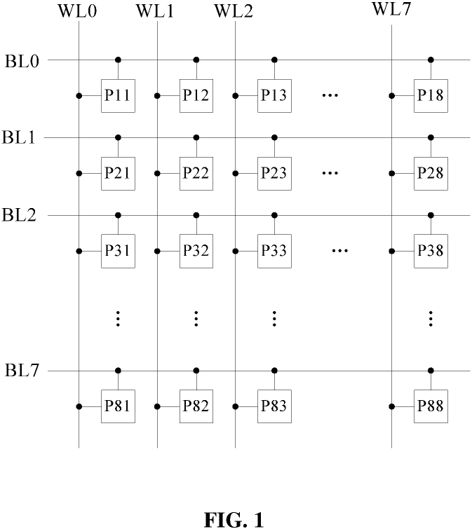

Referring to FIG. 1, FIG. 1 is a layout diagram of a memory chip according to an embodiment of the present disclosure.

In some embodiments, taking a bank in the DRAM as an example, multiple BLs may be divided into 128 BL groups, each BL group having eight BLs. BLs in each BL group are denoted as BL0, BL1, BL2, ...... BL7 for convenience of the following description. Multiple WLs may be divided into 8192 WL groups, each WL group having eight WLs. WLs in each WL group are denoted as WL0, WL1, WL2, ...... WL7 for convenience of the following description.

Multiple memory cells P11-P88 are distributed in a matrix, herein the memory cells in the first column are all connected to the WL0, the memory cells in the second column are all connected to the WL1, and so on, and the memory cells in the eighth column are all connected to the WL7. The memory cells of the first row are all connected to the BL0, the memory cells of the second row are all connected to the BL1, and so on, and the memory cells of the eighth row are all connected to the BL7. Such that each memory cell is connected to a WL and a BL.

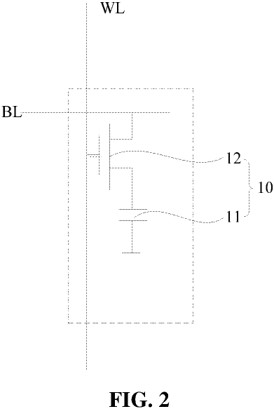

Referring to FIG. 2, FIG. 2 is a schematic structural diagram of a memory cell of a memory chip according to an embodiment of the present disclosure.

In some embodiments, each memory cell 10 includes a transistor 12 and a capacitor 11, the gate of the transistor 12 is connected to the WL, the source of the transistor 12 is connected to the BL, and the drain of the transistor 12 is connected to the capacitor 11. It should be noted that the source of the transistor 12 may be connected to the capacitor 11, and accordingly, the drain of the transistor 12 is connected to the BL.

In some embodiments, when the signal on the WL turns on the switching transistor T, the BL may write a high level signal “1” into the storage capacitor C. When the signal on the WL turns off the switching transistor T, the charge on the storage capacitor C slowly leaks over time. The leakage time of the storage capacitor C from the high level signal “1” to the low level signal “0” is the data storage time of storage capacitor C. The data storage time of the storage capacitor C must be longer than the preset time to realize the dynamic storage function of the dynamic random access memory.

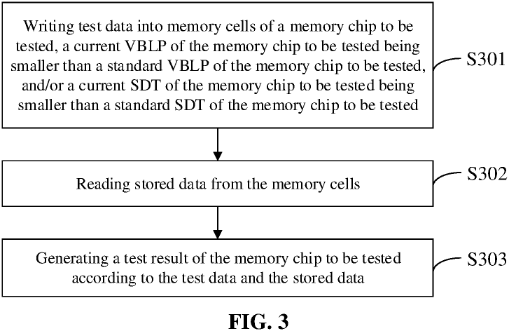

Referring to FIG. 3, FIG. 3 is a schematic flowchart of a method for testing a memory chip according to an embodiment of the present disclosure. In a possible embodiment, the method for testing the memory chip includes the following operations.

At block S301, test data is written into memory cells of a memory chip to be tested.

A current voltage of bit line precharge (VBLP) of the memory chip to be tested is smaller than a standard VBLP of the memory chip to be tested, and/or a current sensing delay time (SDT) of the memory chip to be tested is smaller than a standard SDT of the memory chip to be tested.

At block S302, stored data is read from the memory cells.

At block S303, a test result of the memory chip to be tested is generated according to the test data and the stored data.

In some embodiments, the above-described memory chip to be tested is, for example, a DRAM. Lowering the VBLP to be smaller than the standard VBLP of the DRAM can create poorer operating conditions for the DRAM, reduce the signal margin, and make it easier to expose the failed memory cells in the DRAM.

Lowering the SDT to be smaller than the standard SDT of the DRAM can also create poorer operating conditions for the DRAM, reduce the charge sharing (ΔV), and make it easier to expose failed memory cells in the DRAM.

In a possible embodiment, the VBLP may be lowered to the P% of the standard VBLP, herein 0 <P< 1.

In a possible embodiment, the SDT may be lowered to the Q% of the standard SDT, herein 0<Q<1.

In some embodiments, only the current VBLP of the memory chip to be tested may be adjusted to be smaller than the standard VBLP of the memory chip to be tested.

In some embodiments, only the current SDT of the memory chip to be tested may be adjusted to be smaller than the standard SDT of the memory chip to be tested.

In some embodiments, the current VBLP of the memory chip to be tested may be adjusted to be smaller than the standard VBLP of the memory chip to be tested, and the current SDT of the memory chip to be tested may also be adjusted to be smaller than the standard SDT of the memory chip to be tested.

According to the method for testing a memory chip provided in the embodiments of the present disclosure, on the premise that the VBLP is lowered and/or the SDT is lowered, test data is written into memory cells of a memory chip to be tested, and then stored data in each memory cell is read. It can be determined whether a failed memory cell exists in each memory cell of the memory chip to be tested by comparing the test data with the stored data, and the method can be applied to detecting a failed memory cell in the memory chip due to a failure of storing a low level “0”.

Based on the content described in the above embodiments, in some embodiments, the current write timing parameter of the memory chip to be tested may be further adjusted to be smaller than the standard write timing parameter of the memory chip to be tested, and/or the current read timing parameter of the memory chip to be tested may be adjusted to be smaller than the standard read timing parameter of the memory chip to be tested.

In some embodiments, the write timing parameter may be a write recovery time (TWR) of the memory chip to be tested. The read timing parameter is a row precharge time (TRP) of the memory chip to be tested.

After the DRAM has received the data, it needs a certain time to write the data into respective memory cells of the DRAM, and the certain time is defined as the TWR. The value indicates how many clock cycles must be waited before a valid write operation and precharge is completed in an active memory bank. The necessary clock cycle is used to ensure that the data in the write buffer can be written into the memory cells before the precharge occurs.

The TRP is the time between the precharge (PRE) command and the active (ACT) command of the next WL in the DRAM, which is used to characterize the speed at which the DRAM bank is restored to the precharge state, in particular the time required for the BL in the bank to be charged from the high level or the low level to the intermediate potential.

Shortening the TER of the memory chip to be tested is equivalent to creating a condition of insufficient writing for the memory chip to be tested. Shortening the TRP of the memory chip to be tested is equivalent to creating a condition of insufficient reading for the memory chip to be tested.

In a possible embodiment, the TWR may be shortened to the R% of the standard TWR, herein 0 < R< 1.

In a possible embodiment, the TRP may be shortened to the S% of the standard TRP, herein 0<S<1.

In some embodiments, the TWR of the memory chip to be tested may be shortened only, or the TRP of the memory chip to be tested may be shortened only.

In some embodiments, both the TWR of the memory chip to be tested and the TRP of the memory chip to be tested may be shortened.

In some embodiments, the TWR of the memory chip to be tested and/or the TRP of the memory chip to be tested may be shortened on the premise that the current VBLP of the memory chip to be tested is adjusted to be smaller than the standard VBLP of the memory chip to be tested, and/or the current SDT of the memory chip to be tested is adjusted to be smaller than the standard SDT of the memory chip to be tested.

Exemplarily, in a possible embodiment, the current VBLP of the memory chip to be tested may be adjusted to be smaller than the standard VBLP of the memory chip to be tested, and the current SDT of the memory chip to be tested may be adjusted to be smaller than the standard SDT of the memory chip to be tested, thereby creating poorer operating conditions for the memory chip to be tested. Furthermore, on the premise that the TWR of the memory chip to be tested is shortened, the test data is written into the memory cells of the memory chip to be tested to create a condition of insufficient writing. Then, on the premise that the TRP of the memory chip to be tested is shortened, the stored data is read from the memory cells to create a condition of insufficient reading. Comparing whether the read stored data is the same as the written test data, and if the same, it means that no failed memory cell exists in the memory chip to be tested. If not, it means that a failed memory cell exists in the memory chip to be tested.

It may be understood that, in some embodiments, any one, two or three of the VBLP, the SDT, the write timing parameter, the read timing parameter may be reduced. Various combinations are not described herein.

According to the method for testing a memory chip provided in the embodiment of the present disclosure, after a poorer operating condition is created for a memory chip to be tested, the stored data is written in a case where a TWR is shortened, and the stored data is read from the memory cells in a case where a TRP is shortened. It can create a double harsh condition for detecting a memory cell that fails due to a failure of storing a low level “0”, and make the memory cell that fails due to the failure of storing the low level “0” more easily exposed, thereby indicating effectively the accuracy of detection results.

Based on the content described in the above embodiments, in some embodiments, the memory chip to be tested includes multiple columns of memory cells, and each column of memory cells employ at least one detection cycle. When test data is written into the memory cells of the memory chip to be tested, the test data may be written into memory cells within a same detection cycle. Similarly, when the stored data is read from the memory cells, the stored data is also read from the memory cells in the same detection cycle.

Alternatively, each column of memory cells of the memory chip to be tested may be tested in a traversal manner along an X-axis direction.

In some embodiments, the memory chip to be tested includes multiple rows of memory cells, and each row of memory cells employ at least one detection cycle. When the test data is written into the memory cells of the memory chip to be tested, the test data may be written into memory cells within a same detection cycle. Similarly, when the stored data is read from the memory cells, the stored data is also read from the memory cells in the same detection cycle.

Alternatively, each row of memory cells of the memory chip to be tested may be tested in a traversal manner along a Y-axis direction.

In some embodiments, the test data is multiple binary sequences having equal data bits, and each of the binary sequences has a different data topology.

Alternatively, the above test data may be determined in the following manner:

at least one data bit of the test data is taken as a conversion bit, traversal access to the test data is performed, and data of the conversion bit having been accessed by traversing is inverted until each binary sequence in the test data is traversed.

In some embodiments, a number of bits of the memory cells in each row or column of the memory chip to be tested is greater than a number of bits of the test data.

In some embodiments, a number of bits of the memory cells in each row or column of the memory chip to be tested is an integer multiple of a number of bits of the test data.

In some embodiments, the test data includes multiple binary sequences, and each of the binary sequences has and only one data bit being 0.

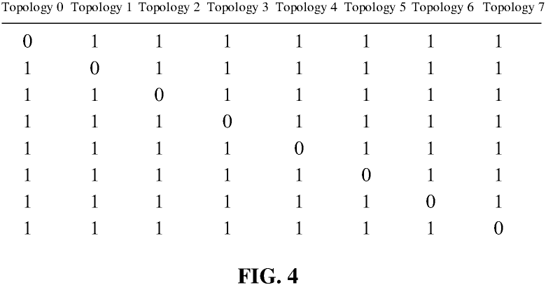

For better understanding, referring to FIG. 4, FIG. 4 is a schematic diagram of multiple data topologies of test data provided in an embodiment of the present disclosure.

In FIG. 4, the number of bits for each test data is 8 bits, and one and only one data bit in each binary sequence is 0.

According to the method for testing a memory chip provided in the embodiment of the present disclosure, the binary sequence in the above form is used as the test data to detect memory cells in the memory chip effectively.

In some embodiments, the data 1 is written into each memory cell of the memory chip to be tested before the test data is written into the memory cells of the memory chip to be tested, and each memory cell of the memory chip to be tested is stored back to data 1 after the test is finished.

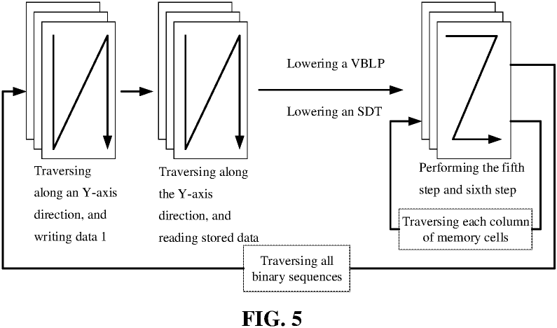

In a possible embodiment, referring to FIG. 5, FIG. 5 is a schematic flowchart of a method for testing a memory chip provided in an embodiment of the present disclosure. The method for testing the memory chip includes the following steps.

At the first step, the memory cells of the memory chip to be tested are traversed along the Y-axis direction, and the data 1 is written into the traversed memory cells.

At the second step, the memory cells of the memory chip to be tested are traversed along the Y-axis direction, and the stored data in the traversed memory cells is read.

At the third step, it is determined whether all the read data in the second step are 1. If all the read data are 1, the fourth step is performed. If the read data contains 0, it is determined that a failed memory cell exists in the memory chip to be tested, and the failed memory cell is a memory cell whose read data is 0.

At the fourth step, the current VBLP of the memory chip to be tested and/or the current SDT are lowered.

At the fifth step, on the premise of shortening the write timing parameter, a column of memory cells of the memory chip to be tested is traversed along the X-axis direction, and a binary sequence is written into the column of memory cells having been traversed.

At the sixth step, on the premise of shortening the reading timing parameter, a column of memory cells of the memory chip to be tested is traversed along the X-axis direction, and the binary sequence stored in the column of memory cells having been traversed is read.

After reading the binary sequence stored in the column of memory cells having been traversed, data 1 is written into the column of memory cells having been traversed currently.

The fifth step and sixth step are repeated to traverse each column of memory cells of the memory chip to be tested.

At the seventh step, the remaining binary sequences are traversed, and the first to sixth steps are repeated.

In the embodiment, after all the binary sequences are traversed, the test result of the memory chip to be tested is generated according to the written test data and the read stored data.

In a possible embodiment, the test data may be compared with the stored data, and it is determined whether a read or write error occurs in the memory cells of the memory chip to be tested according to a comparison result. In response to that the read or write error occurs in the memory cells of the memory chip to be tested, a bit on which the read or write error occurs is determined according to the comparison result. The test result of the memory chip to be tested is generated according to a determination result of whether a read or write error occurs in the memory cells of the memory chip to be tested.

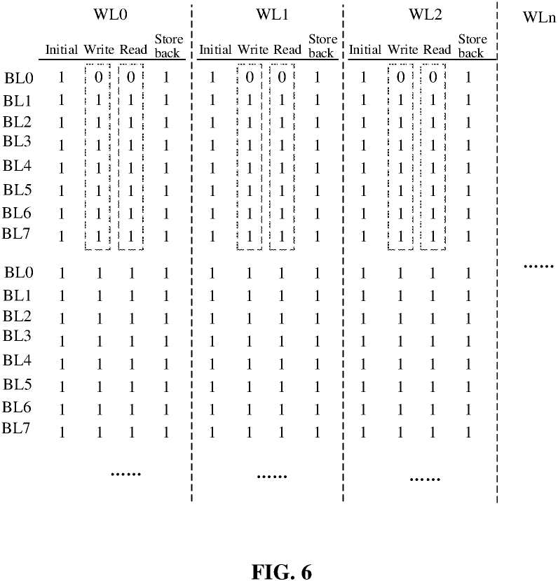

To better understand the embodiment of the present disclosure, referring to FIG. 6, FIG. 6 is a first schematic diagram of a data writing flow of a method for testing a memory chip provided in the embodiment of the present disclosure.

In FIG. 6, taking a bank in the DRAM as an example, multiple BLs may be divided into 128 BL groups, each BL group having eight BLs, and BLs in each BL group are denoted as BL0, BL1, BL2, ...... BL7 for convenience of the following description.

Multiple WLs may be divided into 8192 WL groups, each WL group having eight WLs, and WLs in each WL group are denoted as WL0, WL1, WL2, ...... WL7 for convenience of the following description.

Multiple memory cells are distributed in a matrix, herein the memory cells in the first column are all connected to the WL0, the memory cells in the second column are all connected to the WL1, and so on, and the memory cells in the eighth column are all connected to the WL7. The memory cells of the first row are all connected to the BL0, the memory cells of the second row are all connected to the BL1, and so on, and the memory cells of the eighth row are all connected to the BL7. Such that each memory cell is connected to a WL and a BL.

In some embodiments, the current VBLP of the memory chip to be tested is pre-adjusted to be smaller than the standard VBLP of the memory chip to be tested, and the current SDT of the memory chip to be tested is pre-adjusted to be smaller than the standard SDT of the memory chip to be tested, thereby creating poorer operating conditions for the memory chip to be tested. Under this operating condition, after adjusting the current write timing parameter of the memory chip to be tested to be smaller than the standard write timing parameter of the memory chip to be tested, each WL (WL0, WL1, WL2, ...... WL7) of the memory chip to be tested is traversed along the X-axis direction, and a binary sequence (e.g. topology 0) 01111111 is written into a column of memory cells corresponding a set of BLs (BL0, BL1, BL2, ...... BL7) of each WL. Then, the current reading timing parameter of the memory chip to be tested is adjusted to be smaller than the standard reading timing parameter of the memory chip to be tested, and stored data in a column of memory cells having been traversed is read.

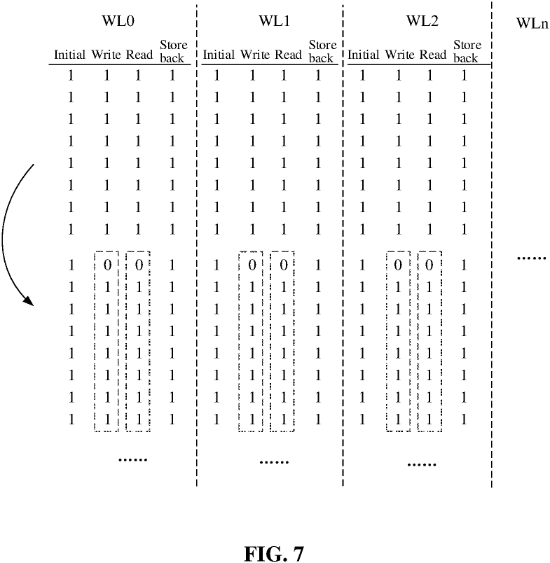

Referring to FIG. 7, FIG. 7 is a second schematic diagram of a data writing flow of a method for testing a memory chip provided in an embodiment of the present disclosure.

In FIG. 7, after a row of BL groups are traversed along the X-axis direction, traversal of the second row of BL groups is started in the same manner. The above-described binary sequence (topology 0) 01111111 is written into each column of memory cells of the second row of BL groups until the last column of memory cells in the last row of BL groups.

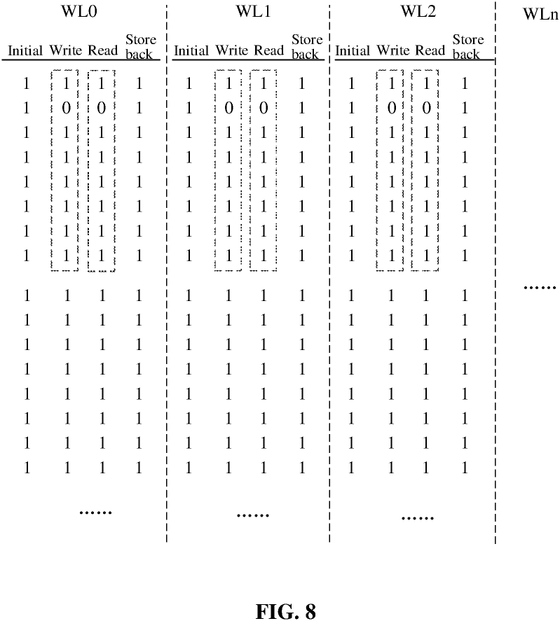

Referring to FIG. 8, FIG. 8 is a third schematic diagram of a data writing flow of a method for testing a memory chip provided in an embodiment of the present disclosure.

After all the BL groups are traversed, each WL (WL0, WL1, WL2......WL7) of the memory chip to be tested is traversed along the X-axis direction in the same manner, and a binary sequence (e.g. topology 1) 10111111 is written into a column of memory cells corresponding a set of BLs (BL0, BL1, BL2 ...... BL7) of each WL. Then, the current reading timing parameter of the memory chip to be tested is adjusted to be smaller than the standard reading timing parameter of the memory chip to be tested, and stored data in a column of memory cells having been traversed is read.

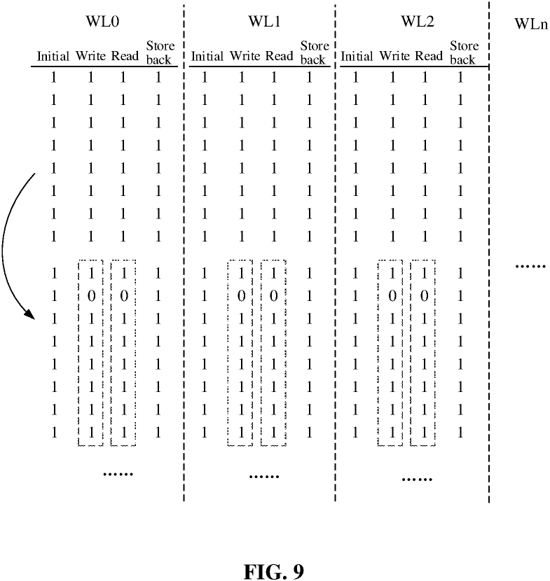

Referring to FIG. 9, FIG. 9 is a fourth schematic diagram of a data writing flow of a method for testing a memory chip provided in an embodiment of the present disclosure.

In FIG. 9, after a row of BL groups are traversed along the X-axis direction, traversal of the second row of BL groups is started in the same manner, and the above-described binary sequence (e.g., topology 1) 10111111 is written into each column of memory cells of the second row of BL groups until the last column of memory cells in the last row of BL groups.

In the above manner, after all the binary sequences in the test data are traversed, the test result of the memory chip to be tested can be obtained by comparing the above test data with the stored data read from the memory chip to be tested.

According to the method for testing a memory chip provided in the embodiments of the application, the memory chip can be placed in a poorer operating environment by adjusting that a current VBLP of a memory chip to be tested is smaller than a standard VBLP of the memory chip to be tested, and/or a current SDT of the memory chip to be tested is smaller than a standard SDT of the memory chip to be tested. Further, the test data is written into the memory cells of the memory chip to be tested under the condition that the current write timing parameter of the memory chip to be tested is smaller than the standard write timing parameter, and the stored data is read from the memory cells under the condition that the current read timing parameter of the memory chip to be tested is smaller than the standard read timing parameter, so that the failed memory cell existing in the memory chip is more easily exposed. It is possible to accurately detect whether the failed memory cell exists in memory chip according to the test data and the read stored data, thereby improving the yield of the memory chip.

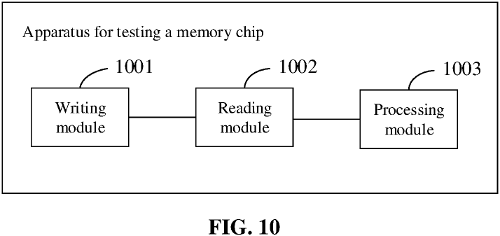

Based on the contents described in the above embodiments, an apparatus for testing a memory chip is further provided in an embodiment of the present disclosure. Referring to FIG. 10, FIG. 10 is a schematic diagram of a program module of an apparatus for testing a memory chip according to an embodiment of the present disclosure. The apparatus for testing the memory chip includes a writing module 1001, a reading module 1002 and a processing module 1003.

The writing module 1001 is configured to write test data into memory cells of a memory chip to be tested.

The reading module 1002 is configured to read stored data from the memory cells.

The processing module 1003 is configured to generate a test result of the memory chip to be tested according to the test data and the stored data.

A current VBLP of the memory chip to be tested is smaller than a standard VBLP of the memory chip to be tested, and/or a current SDT of the memory chip to be tested is smaller than a standard SDT of the memory chip to be tested.

According to the apparatus for testing the memory chip provided in the embodiment of the present disclosure, since the current VBLP of the memory chip to be tested is smaller than the standard VBLP of the memory chip to be tested, and/or the current SDT of the memory chip to be tested is smaller than the standard SDT of the memory chip to be tested, the memory chip is in a poorer operating environment, it is possible to make the abnormality in the memory chip more easily exposed, thereby accurately detecting whether the memory chip is abnormal, and further improving the yield of the memory chip.

In a possible embodiment, a current write timing parameter of the memory chip to be tested is smaller than a standard write timing parameter of the memory chip to be tested, and/or a current read timing parameter of the memory chip to be tested is smaller than a standard read timing parameter of the memory chip to be tested.

In a possible embodiment, the write timing parameter is a TWR of the memory chip to be tested, and the read timing parameter is a TRP of the memory chip to be tested.

In a possible embodiment, the memory chip to be tested includes multiple columns of memory cells, and each column of memory cells employ at least one detection cycle.

The writing module 1001 is configured to write the test data into memory cells within a same detection cycle.

The reading module 1002 is configured to read the stored data from the memory cells within the same detection cycle.

In a possible embodiment, each column of memory cells of the memory chip to be tested are tested in a traversal manner, and a traversal direction is an X-axis direction.

In a possible embodiment, the memory chip to be tested includes multiple rows of memory cells, and each row of memory cells employ at least one detection cycle.

The writing module 1001 is configured to write the test data into memory cells within a same detection cycle.

The reading module 1002 is configured to read the stored data from the memory cells in the same detection cycle.

In a possible embodiment, each row of memory cells of the memory chip to be tested are tested in a traversal manner, and a traversal direction is a Y-axis direction.

In a possible embodiment, the test data is multiple binary sequences having equal data bits, and each of the binary sequences has a different data topology.

In a possible embodiment, the apparatus for testing the memory chip includes a test data generation module, and the test data is determined in a following manner:

at least one data bit of the test data is taken as a conversion bit, traversal access to the test data is performed, and data of the conversion bit having been accessed by traversing is inverted until each binary sequence in the test data is traversed.

In a possible embodiment, a number of bits of the memory cells in each row or column of the memory chip to be tested is greater than a number of bits of the test data.

In a possible embodiment, a number of bits of the memory cells in each row or column of the memory chip to be tested is an integer multiple of the number of bits of the test data.

In a possible embodiment, the test data includes multiple binary sequences, and each of the binary sequences has and only one data bit being 0.

In a possible embodiment, the processing module 1003 is configured to:

compare the test data with the stored data; determine whether a read or write error occurs in the memory cells of the memory chip to be tested according to a comparison result, herein in response to that the read or write error occurs in the memory cells of the memory chip to be tested, a bit on which the read or write error occurs is determined according to the comparison result; and generate the test result of the memory chip to be tested according to a determination result of whether a read or write error occurs in the memory cells of the memory chip to be tested.

In a possible embodiment, the writing module 1001 is further configured to:

before writing the test data into the memory cells of the memory chip to be tested, write data 1 into each memory cell of the memory chip to be tested.

In a possible embodiment, the reading module 1002 is further configured to: after generating the test result of the memory chip to be tested according to the test data and the stored data, store back each memory cell of the memory chip to be tested to data 1.

It should be noted that, in the embodiments of the application, the specific execution content of the writing module 1001, the reading module 1002, and the processing module may be referred to the related contents in the embodiments illustrated in FIGS. 1 to 9, and details are not described herein.

Further, based on the content described in the above embodiments, an electronic device is further provided in the embodiments of the present disclosure, the electronic device including at least one processor and a memory. The memory stores computer-executable instructions. The at least one processor executes the computer-execution instructions stored in the memory to implement the operations in the method for testing the memory chip described in the above embodiment, and details are not described herein again in this embodiment.

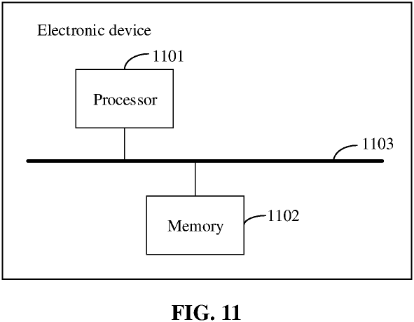

In order to better understand the embodiment of the present disclosure, reference is made to FIG. 11, which is a schematic diagram of a hardware structure of an electronic device according to an embodiment of the present disclosure.

As illustrated in FIG. 11, the electronic device 110 of the embodiment includes a processor 1101 and a memory 1102.

The memory 1102 is configured to store computer-executable instructions.

The processor 1101 is configured to execute the computer-executable instructions stored in the memory to implement the operations in the method for testing the memory chip described in the above embodiment, and details are not described herein again in the embodiment.

Alternatively, the memory 1102 may be either independent or integrated with the processor 1101.

When the memory 1102 is provided independently, the device further includes a bus 1103 for connecting the memory 1102 and the processor 1101.

Further, based on the content described in the foregoing embodiment, a computer-readable storage medium is further provided in the embodiments of the present disclosure. The computer-readable storage medium having stored thereon computer-executable instructions that, when being executed by a processor, cause the processor to implement each operation in the method for testing the memory chip described in the foregoing embodiment is implemented. Details are not described herein again in the embodiment.

In several embodiments provided herein, it should be appreciated that the disclosed device and method may be implemented in other ways. For example, the device embodiments described above are merely illustrative. For example, the division of the module, which is merely a logical function division, may be implemented in another division in the actual implementation. For example, multiple modules may be combined or integrated into another system, or some features may be ignored or not performed. In addition, the illustrated or discussed coupling or direct coupling or communication connection between each other may be indirect coupling or communication connection through some interfaces, devices or modules, may be electrical, mechanical or other.

The modules described as separate components may or may not be physically separate, and the components displayed as modules may or may not be physical units, i.e., may be located in one place, or may be distributed over multiple network units. Some or all of the modules may be selected according to actual needs to achieve the purpose of the solution of the embodiment.

In addition, each functional module in each embodiment of the present disclosure may be integrated into a processing unit, or each module may exist alone physically, or two or more modules may be integrated into a unit. The module-integrated unit may be realized in the form of hardware or in the form of hardware plus software functional units.

The above integrated modules in the form of software functional modules may be stored in a computer-readable storage medium. The software functional modules are stored in a storage medium and include some instructions to cause a computer device (which may be a personal computer, a server, or a network device, etc.) or a processor to perform some of the operations of the method described in various embodiments of the present disclosure.

It should be understood that the processor may be a central processing unit (CPU), or may be another general purpose processor, a digital signal processor (DSP), an application specific integrated circuit (ASIC), or the like. The general purpose processor may be a microprocessor or may be any conventional processor or the like. The operations of the method disclosed in the application may be directly represented as being performed by the hardware processor, or by a combination with hardware and software modules in the processor.

The memory may include a high-speed RAM memory, may also include a non-volatile memory (NVM), such as at least one magnetic disk memory, may also be a USB flash drive, a removable hard disk, a read-only memory, a magnetic disk or an optical disk, or the like.

The bus may be an industry standard architecture (ISA) bus, a peripheral component interconnect (PCI) bus, an extended industry standard architecture (EISA) bus, or the like. The bus may be divided into an address bus, a data bus, a control bus, and the like. For ease of illustration, the bus in the drawings of the present disclosure is not limited to only one bus or one type of bus.

The storage medium may be implemented by any type of volatile or non-volatile storage device or combination thereof, such as static random access memory (SRAM), electrically erasable programmable read only memory (EEPROM), erasable programmable read only memory (EPROM), programmable read only memory (PROM), read only memory (ROM), magnetic memory, flash memory, magnetic disk or optical disk. The storage medium may be any available medium accessible to a general purpose or special purpose computer.

An exemplary storage medium is coupled to the processor, thereby enabling the processor to read information from and write information into the storage medium. Of course, the storage medium may also be part of the processor. The processor and storage medium may be located in an application specific integrated circuit (ASIC). Of course, processors and storage medium may also exist as discrete components in an electronic device or a master device.

It will be appreciated by those of ordinary skill in the art that all or part of the operations of implementing the above-described method embodiments may be accomplished by program instructions related hardware. The program may be stored in a computer-readable storage medium. When the program is executed, the operations including the above-described method embodiments are executed. The aforementioned storage medium includes various types of medium that can store program code, such as ROM, RAM, magnetic disk, or optical disc.

Finally, it should be noted that the above embodiments are merely intended to illustrate the technical solution of the present disclosure, but not limited thereto. Although the present disclosure has been described in detail with reference to the foregoing embodiments, it should be understood by those of ordinary skill in the art that modifications may still be made to the technical solutions described in the foregoing embodiments, or equivalent substitutions may be made to some or all of the technical features thereof. These modifications or substitutions do not leave the essence of the corresponding technical solutions out of the scope of the technical solutions of the embodiments of the present disclosure.

What is claimed is:

1. A method for testing a memory chip, comprising:
writing test data into memory cells of a memory chip to be tested;
reading stored data from the memory cells; and
generating a test result of the memory chip to be tested according to the test data and the stored data,
wherein a current voltage of bit line precharge of the memory chip to be tested is smaller than a standard voltage of bit line precharge of the memory chip to be tested, and/or a current sensing delay time of the memory chip to be tested is smaller than a standard sensing delay time of the memory chip to be tested.

2. The method of claim 1, wherein a current write timing parameter of the memory chip to be tested is smaller than a standard write timing parameter of the memory chip to be tested, and/or a current read timing parameter of the memory chip to be tested is smaller than a standard read timing parameter of the memory chip to be tested.

3. The method of claim 2, wherein the write timing parameter is a time of write recovery of the memory chip to be tested, and the read timing parameter is a time of row precharge of the memory chip to be tested.

4. The method of claim 1, wherein the memory chip to be tested comprises a plurality of columns of memory cells, and each column of memory cells employ at least one detection cycle;
wherein writing the test data into the memory cells of the memory chip to be tested comprises:
writing the test data into memory cells within a same detection cycle; and
wherein reading the stored data from the memory cells comprises:
reading the stored data from the memory cells within the same detection cycle.

5. The method of claim 4, wherein each column of memory cells of the memory chip to be tested are tested in a traversal manner, and a traversal direction is an X-axis direction.

6. The method of claim 1, wherein the memory chip to be tested comprises a plurality of rows of memory cells, and each row of memory cells employ at least one of detection cycle;
wherein writing the test data into the memory cells of the memory chip to be tested comprises:
writing the test data into memory cells within a same detection cycle; and
wherein reading the stored data from the memory cells comprises:
reading the stored data from the memory cells within the same detection cycle.

7. The method of claim 6, wherein each row of memory cells of the memory chip to be tested are tested in a traversal manner, and a traversal direction is a Y-axis direction.

8. The method of claim 1, wherein the test data is a plurality of binary sequences having equal data bits, and each of the binary sequences has a different data topology.

9. The method of claim 8, further comprising:
determining the test data in a following manner:
taking at least one data bit of the test data as a conversion bit, performing traversal access to the test data, and inverting data of the conversion bit that has been accessed by traversing until each binary sequence in the test data is traversed.

10. The method of claim 8, wherein a number of bits of the memory cells in each row or column is greater than a number of bits of the test data.

11. The method of claim 8, wherein a number of bits of the memory cells in each row or column is an integer multiple of a number of bits of the test data.

12. The method of claim 1, wherein the test data comprises a plurality of binary sequences, and each of the binary sequences has and only one data bit being 0.

13. The method of claim 1, wherein generating the test result of the memory chip to be tested according to the test data and the stored data comprises:
comparing the test data with the stored data, and determining whether a read or write error occurs in the memory cells of the memory chip to be tested according to a comparison result, wherein in response to that the read or write error occurs in the memory cells of the memory chip to be tested, a bit on which the read or write error occurs is determined according to the comparison result; and
generating the test result of the memory chip to be tested according to a determination result of whether a read or write error occurs in the memory cells of the memory chip to be test.

14. The method of claim 1, wherein before writing the test data into the memory cells of the memory chip to be tested, the method further comprises:
writing data 1 into each memory cell of the memory chip to be tested.

15. The method of claim 1, wherein after generating the test result of the memory chip to be tested according to the test data and the stored data, the method further comprises:
storing back each memory cell of the memory chip to be tested to data 1.

16. An electronic device, comprising a memory and at least one processor;
wherein the memory is configured to store computer-executable instructions; and
the at least one processor is configured to execute operations of:
writing test data into memory cells of a memory chip to be tested;
reading stored data from the memory cells; and
generating a test result of the memory chip to be tested according to the test data and the stored data,
wherein a current voltage of bit line precharge of the memory chip to be tested is smaller than a standard voltage of bit line precharge of the memory chip to be tested, and/or a current sensing delay time of the memory chip to be tested is smaller than a standard sensing delay time of the memory chip to be tested.

17. The electronic device of claim 16, wherein a current write timing parameter of the memory chip to be tested is smaller than a standard write timing parameter of the memory chip to be tested, and/or a current read timing parameter of the memory chip to be tested is smaller than a standard read timing parameter of the memory chip to be tested.

18. The electronic device of claim 17, wherein the write timing parameter is a time of write recovery of the memory chip to be tested, and the read timing parameter is a time of row precharge of the memory chip to be tested.

19. The electronic device of claim 16, wherein the memory chip to be tested comprises a plurality of columns of memory cells, and each column of memory cells employ at least one detection cycle;
wherein when writing the test data into the memory cells of the memory chip to be tested, the at least one processor is further configured to:
write the test data into memory cells within a same detection cycle; and
wherein when reading the stored data from the memory cells, the at least one processor is further configured to:
read the stored data from the memory cells within the same detection cycle.

20. A non-transitory computer-readable storage medium, having stored thereon computer-executable instructions that, when being executed by a processor, cause the processor to implement the method for testing the memory chip of claim 1.
